(19) United States
(12) Patent Application Publication
(10) Pub. No.: US 2004/0164297 A1
(43) Pub. Date: Aug. 26, 2004

(54) Display device

(76) Inventors: Toshiki Kaneko, Chiba (JP); Daisuke Sonoda, Mobara (JP); Takahiro Ochiai, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/772,432

(22) Filed: Feb. 6, 2004

(30) Foreign Application Priority Data
Feb. 19, 2003 (JP) 2003-040724

(51) Int. Cl. H01L 29/04

(52) U.S. Cl. 257/59

(57) ABSTRACT

The present invention provides a display device provided with the gate signal lines and the gate electrodes of the thin film transistors which can prevent the generation of hillock and can reduce the resistance in spite of having the simple structure. In a display device having thin film transistors on a substrate thereof, the display device includes gate patterns in each of which a gate line and a gate electrode of the thin film transistor are integrally formed, the gate pattern is constituted by at least three-layered films consisting of a lowermost layer, an intermediate layer formed of at least one layer and an uppermost layer at least at either a portion of the thin film transistor or a portion of the gate pattern which crosses a drain line, and end portions of the intermediate layer are retracted from end portions of the uppermost layer and end portions of the lowermost layer.

### BACKGROUND OF THE INVENTION

The present invention relates to a display device, and more particularly to a display device which includes thin film transistors each of which includes a semiconductor layer made of polysilicon.

For example, in an active matrix type liquid crystal display device, on a liquid-crystal-side surface of one substrate out of a pair of substrates which are arranged to face each other with liquid crystal therebetween, gate signal lines which extend in the x direction and are arranged in parallel in the y direction and drain signal lines which extend in the y direction and are arranged in parallel in the x direction are formed, and regions which are surrounded by these respective signal lines constitute pixel regions.

Then, each pixel region at least includes a thin film transistor which is driven in response to scanning signals from the gate signal line and a pixel electrode to which video signals from the drain signal line are supplied through the thin film transistor.

Here, as the thin film transistor, a thin film transistor which uses polysilicon for forming a semiconductor layer at a low temperature has been known. With the use of such a thin film transistor, high-speed switching can be performed.

Further, the enhancement of functions and the reduction of cost can be achieved by a following constitution. That is, a peripheral drive circuit for supplying the scanning signals to the gate signal lines or a peripheral drive circuit for supplying the video signals to the drain signal lines is formed on one substrate, polysilicon is used as a material of a semiconductor layer of each transistor which is incorporated into the peripheral drive circuit, and the transistor is formed in parallel with the thin film transistor within the pixel region.

On the other hand, along with the increase of size of a liquid crystal display device, the further reduction of resistance of the gate signal lines is requested.

In this case, it is proper to use aluminum as a material of the gate signal lines. However, it has been found that aluminum does not exhibit the sufficient heat resistance against heat of activated annealing of the polysilicon semiconductor layer, for example.

Accordingly, as the gate signal line, a gate signal line which uses a high-melting-point metal as a material of a lower layer and stacks a barrier layer on the lower layer (see Japanese Unexamined Patent Publication Hei10 (1998)-247733 (hereinafter referred to as patent literature 1)), a gate signal line which forms a cap layer above an aluminum line and forms a barrier layer on side faces of the aluminum line (see Japanese Unexamined Patent Publication Hei11 (1999)-87716 (hereinafter referred to as patent literature 2)), and a gate signal line which is made of an aluminum layer and has upper and lower layers thereof covered with a high-melting-point metal (see Japanese Unexamined Patent Publication Hei6 (1994)-148683 (hereinafter referred to as patent literature 3)) and the like have been known.

Further, the gate signal lines are usually formed integrally with gate electrodes of the thin film transistors and the thin film transistors are, for preventing the degradation of characteristics thereof by obviating a direct contact thereof with liquid crystal, covered with an insulation film which is referred to as a protective film, for example. Here, it is important to judge whether the gate signal lines are favorably covered with the insulation film or not (see Japanese Unexamined Patent Publication Hei11 (1999)-135797 (hereinafter referred to as patent literature 4)).

### SUMMARY OF THE INVENTION

However, with respect to the liquid crystal display devices which are described in the above-mentioned respective literatures, since the aluminum layer is exposed from the side surfaces of the gate signal line, there has been a drawback that a so-called hillock is grown from the aluminum layer (patent literature 4).

Further, even when an alloy element is added to prevent the generation of the hillock, there arises a drawback that the electric resistance is largely increased (patent literature 1).

Further, any countermeasure to prevent the generation of the hillock in the periphery of the gate signal line including the side surface may give rise to a drawback that the countermeasure has the complicated constitution which requires the increase of man-hours for manufacturing (patent literature 2).

The present invention has been made under such circumstances and it is an advantage of the present invention to provide a display device having gate signal lines and gate electrodes of thin film transistors which can reduce the resistance while preventing the generation of a hillock in spite of the simple structure thereof.

To briefly explain representative inventions among the inventions disclosed in this specification, they are as follows.

Means 1.

The present invention is directed to, for example, a display device having thin film transistors on a substrate thereof, wherein

the display device includes gate patterns in each of which a gate line and a gate electrode of the thin film transistor are integrally formed,

the gate pattern is constituted by at least three-layered films consisting of a lowermost layer, an intermediate layer formed of at least one layer and an uppermost layer at least at either a portion of the thin film transistor or a portion of the gate pattern which crosses a drain line, and

end portions of the intermediate layer are retracted from end portions of the uppermost layer and end portions of the lowermost layer.

Means 2.

The display device according to the present invention is, for example, based on the constitution of means 1 and is characterized in that the intermediate layer is formed of a material selected from the group consisting of pure Al, an Al alloy, pure Ag, an Ag alloy, pure Cu and a Cu alloy, and the uppermost layer and the lowermost layer are formed of a metal having a melting point higher than a melting point of the material of the intermediate layer,

Means 3.

The display device according to the present invention is, for example, based on the constitution of means 2 and is characterized in that the uppermost layer and the lowermost layer are formed of pure Mo or an Mo alloy.

Means 4.

The display device according to the present invention is, for example, based on the constitution of means 2 and is characterized in that the uppermost layer and the lowermost layer are formed of an Mo—W alloy.

Means 5.

The display device according to the present invention is, for example, based on the constitution of any one of means 1 to 4 and is characterized in that end portions of the uppermost layer are retracted from end portions of the lowermost layer.

Means 6.

The display device according to the present invention is, for example, based on the constitution of any one of means 1 to 5 and is characterized in that the thin film transistor includes a semiconductor layer and the gate electrode is arranged above the semiconductor layer.

Means 7.

The display device according to the present invention is, for example, based on the constitution of any one of means 1 to 6 and is characterized in that the thin film transistor includes a polycrystalline semiconductor layer.

Means 8.

The present invention is directed to, for example, a display device having thin film transistors on a substrate thereof, wherein

the display device includes gate patterns in each of which a gate line and a gate electrode of the thin film transistor are integrally formed, and an insulation film which covers the gate pattern,

the gate pattern is constituted by at least three-layered films consisting of a lowermost layer, an intermediate layer formed of at least one layer and an uppermost layer at least at either a portion of the thin film transistor or a portion of the gate pattern which crosses a drain line, and

end portions of the uppermost layer of the gate electrode are retracted from end portions of the lowermost layer and, at the same time, end portions of the intermediate layer of the gate electrode are retracted from end portions of the uppermost layer and end portions of the lowermost layer.

Means 9.

The display device according to the present invention is, for example, based on the constitution of means 8 and is characterized in that the thin film transistor includes a semiconductor layer and the gate electrode is arranged above the semiconductor layer.

Means 10.

The display device according to the present invention is, for example, based on the constitution of means 9 and is characterized in that the intermediate layer is formed of a material selected from the group consisting of pure Al, an Al alloy, pure Ag, an Ag alloy, pure Cu and a Cu alloy, and the uppermost layer and the lowermost layer are formed of a metal having a melting point higher than a melting point of the material of the intermediate layer.

Means 11.

The display device according to the present invention is, for example, based on the constitution of means 10 and is characterized in that the uppermost layer and the lowermost layer are formed of pure Mo or an Mo alloy.

Means 12.

The display device according to the present invention is, for example, based on the constitution of means 10 and is characterized in that the uppermost layer and the lowermost layer are formed of an Mo—W alloy.

Means 13.

The display device according to the present invention is, for example, based on the constitution of means 10 and is characterized in that the uppermost layer and the lowermost layer are formed of an Mo alloy, and an etching rate of the Mo alloy of the uppermost layer is faster than an etching rate of Mo alloy of the lowermost layer.

Means 14.

The display device according to the present invention is, for example, based on the constitution of means 13 and is characterized in that the lowermost layer is formed of an Mo—Cr alloy and the uppermost layer is formed of an Mo—W alloy.

Means 15.

The display device according to the present invention is, for example, based on the constitution of any one of means 8 to 14 and is characterized in that the semiconductor layer includes an LDD region, and the lowermost layer of the gate electrode has at least a portion thereof overlapped to the LDD region.

Means 16.

The display device according to the present invention is, for example, based on the constitution of any one of means 8 to 15 and is characterized in that the thin film transistor includes a polycrystalline semiconductor layer.

The present invention is not limited to the above-mentioned constitutions and various modifications are conceivable without departing from the technical concept of the present invention.

### BRIEF DESCRIPTION OF THE DRAWINGS

FIG. 1 is a plan view showing one embodiment of a pixel of a display device according to the present invention;

FIG. 2 is a cross-sectional view taken along a line II-II in FIG. 1;

FIG. 3 is a cross-sectional view taken along a line III-III in FIG. 1;

FIG. 4A to FIG. 4C are views showing essential steps of one embodiment of a manufacturing method of a display device according to the present invention;

FIG. 5 is a cross-sectional view showing another embodiment of the pixel of the display device according to the present invention;

FIG. 6A to FIG. 6C are views showing essential steps of one embodiment of a manufacturing method of a display device shown in FIG. 5;

FIG. 7 is a cross-sectional view showing another embodiment of the pixel of the display device according to the present invention;

FIG. 8 is a cross-sectional view showing another embodiment of the pixel of the display device according to the present invention;

FIG. 9A to FIG. 9C are views showing essential steps of one embodiment of the manufacturing method of the display device shown in FIG. 8;

FIG. 10A and FIG. 10B are views showing essential steps of another embodiment of the manufacturing method of the display device according to the present invention; and

FIG. 11A to FIG. 11C are views showing essential steps of another embodiment of the manufacturing method of the display device according to the present invention.

### DESCRIPTION OF THE PREFERRED EMBODIMENTS

Embodiments of a display device according to the present invention are explained in conjunction with drawings.

<<Constitution of Pixel>>

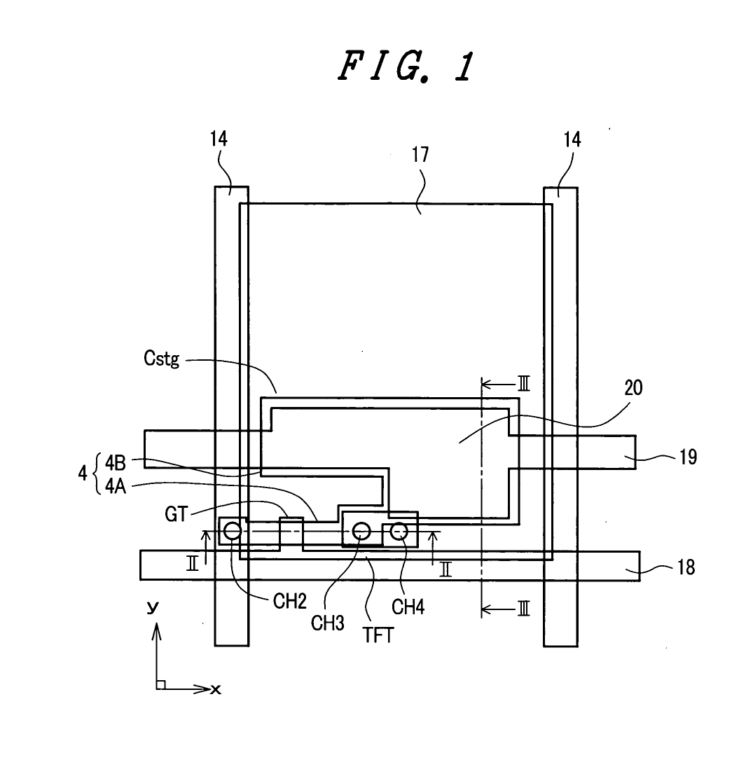

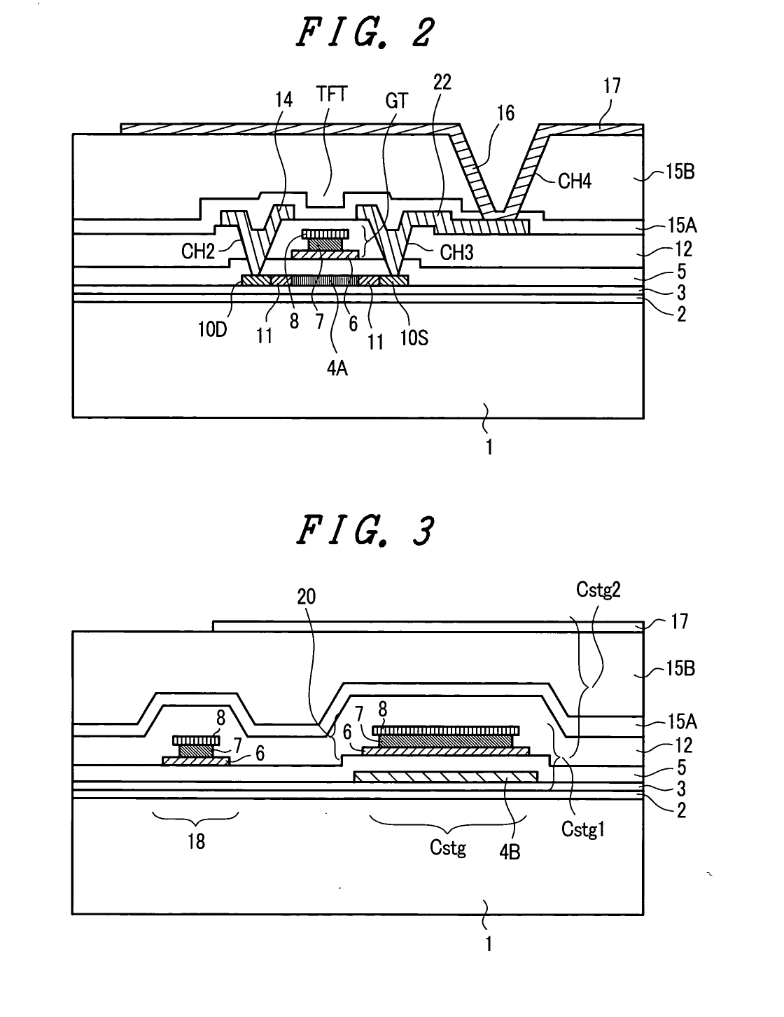

FIG. 1 is a plan view showing the constitution of a pixel of a liquid crystal display device, for example, FIG. 2 is a cross-sectional view taken along a line II-II in FIG. 1, and FIG. 3 is a cross-sectional view taken along a line III-III in FIG. 1.

Here, a liquid crystal display part of the liquid crystal display device is configured such that a large number of pixels are arranged in a matrix array. That is, the pixel shown in FIG. 1 is one of these pixels and the pixels which are arranged at upper and lower peripheral sides and left and right peripheral sides are omitted.

In respective drawing, first of all, a silicon nitride film 2 and a silicon oxide film 3 are sequentially formed over a liquid-crystal-side surface of a transparent insulation substrate 1. The silicon nitride film 2 and the silicon oxide film 3 are formed to prevent ionic impurities contained in the transparent insulation substrate 1 from affecting a thin film transistor TFT described later.

Then, on a surface of the silicon oxide film 3, a semiconductor layer 4 formed of a polysilicon layer, for example, is formed. The semiconductor layer 4 is formed by polycrystallizing an amorphous Si film which is formed by a plasma CVD device, for example, using an excimer laser.

The semiconductor layer 4 is constituted by a strip-like portion 4A which is formed to be arranged close to and substantially parallel to a gate line layer 18 described later and a substantially rectangular portion 4B which is arranged close to the portion 4A, is formed integrally with the portion 4A and occupies a portion of the pixel region.

Here, the silicon nitride film 2, the silicon oxide film 3 and the amorphous Si film before polycrystallization are respectively formed by a plasma CVD method, for example. Thereafter, only the amorphous Si film is selectively etched (for example, dry etching) using a photolithography technique to form the above-mentioned pattern which is constituted by respective portions 4A and 4B.

A semiconductor layer of the strip-like portion 4A is formed as a semiconductor layer of a thin film transistor TFT, while a semiconductor layer of the substantially rectangular portion 4B is formed as one electrode of respective electrodes of a capacitive element Cstg1 described later.

On the surface of the transparent insulation substrate 1 on which such semiconductor layers 4 are formed, a first insulation film 5 made of SiO₂ by a CVD method, for example, is formed such that the first insulation film 5 also covers the semiconductor layers 4.

The first insulation film 5 functions as a gate insulation film in a region where the thin film transistor TFT is formed and, at the same time, functions as one of dielectric films in a region where the capacitive element Cstg1 described later is formed.

Then, on an upper surface of the first insulation film 5, the gate line layers 18 which extend in the x direction in the drawing and are arranged in parallel in the y direction in the drawing are formed. These gate line layers 18 define rectangular pixel regions together with drain line layers 14 described later.

Further, a portion of each gate line layer 18 extends into the inside of the pixel region and is overlapped with the strip-like semiconductor layer 4A in a crossing manner. The extension portion of the gate line layer 18 is formed as a gate electrode GT of the thin film transistor TFT.

Due to such a constitution, the gate line layers 18 and the gate electrodes GT are respectively and integrally formed as a gate pattern, wherein materials of these elements have the same constitution. Hereinafter, in this specification, the gate pattern means the gate line layer 18 and the gate electrode GT which are formed integrally, while the gate line layers 18 and the gate electrode GT maybe used individually when necessary.

Here, the gate pattern has the three-layered structure, for example, wherein a lowermost layer 6 is formed of an Mo—W alloy film, an intermediate layer 7 is formed of an Al—Si alloy film, and an uppermost layer 8 is formed of an Mo—W alloy film.

The reduction of resistance is requested with respect to the gate pattern and hence, as a material of the gate pattern per se, it is desirable to use an Al—Si alloy film. However, in high-temperature annealing which is performed for activating the semiconductor layer 4 in a step after the formation of a second insulation film 12 described later, the Al—Si alloy film exhibits a drawback with respect to the heat resistance. Accordingly, the gate pattern has the above-mentioned three-layered structure using the Mo—W alloy film which is made of metal having a high melting point.

Further, with respect to the gate pattern, the intermediate layer 7 has side surfaces (end portions) formed in a retracted manner from end portions of the lowermost layer 6 and end portions of the uppermost layer 8 such that the end portions of the intermediate layer 7 are scooped with respect to the lowermost layer 6 and the uppermost layer 8. An advantageous effect obtained by such a constitution will be explained later in detail.

Then, in this embodiment, the uppermost layer 8 of the gate pattern is formed such that the end portions thereof are retracted from the end portions of the lowermost layer 6. An advantageous effects obtained by such a constitution are also explained later in detail.

In other words, respective layers of the gate pattern have the center axes in the extending direction substantially aligned with each other, and widths (widths in the direction which crosses the extension direction) are formed to be increased in order of the intermediate layer 7, the uppermost layer 8 and the lowermost layer 6.

After the formation of the gate line layer 18, the ion implantation of impurities is performed by way of the first insulation film 5 and hence, a region of the semiconductor layer 4 except for a portion immediately below the gate electrodes GT is made conductive, whereby a source region 10S and a drain region 10D of the thin film transistor TFT are formed and, at the same time, one electrode out of respective electrodes of the capacitive elements Cstg1 is formed.

On the other hand, to make the semiconductor layer 4B conductive, only the region of the semiconductor layer 4B may be doped with impurities of high concentration in advance and, thereafter, a capacitive signal line 19 may be formed.

Further, in the above-mentioned semiconductor layer 4B, between the region (the channel region) right below the gate electrode GT and the drain region 10D as well as between the channel region and the source region 10S, LDD layers 11 doped with impurities of low concentration are respectively formed. The LDD layers 11 are provided for alleviating the concentration of an electric field which is generated between the drain region 10D or the source region 10S and the gate electrode GT.

Further, in the region close to the semiconductor layer 4A within the pixel region and on the upper surface of the first insulation film 5, the capacitive signal line 19 extending in the x direction in the drawing is integrally formed with a capacitive electrode 20 which has a large width. The capacitive signal line 19 and the capacitive electrode 20 are simultaneously formed with the gate line layer 18, for example. Accordingly, the capacitive signal line 19 and the capacitive electrode 20 are formed on the same layer as the gate line layer 18 and are formed of the same material as the gate line layer 18. Further, the capacitive signal line 19 and the capacitive electrode 20 have the same cross-sectional structure as the gate line layer 18.

In this case, the capacitive electrode 20 is formed such that the capacitive electrode 20 is overlapped with the semiconductor layer 4B and hence, one capacitive element Cstg1 which uses the semiconductor layer 4B as another electrode (connected to the source region 10S of the thin film transistor TFT) and the first insulation film 5 as a dielectric film is formed. Here, the reason that one capacitive element Cstg1 is provided lies in that, as will be explained later, another capacitive element Cstg2 is overlapped with the capacitive element Cstg1 and these capacitive elements are connected in parallel so as to increase the capacitive value.

Then, a second insulation film 12 which is made of SiO₂, for example, is formed over the upper surface of the first insulation film 5 such that the second insulation film 12 also covers the gate wiring layers 18 and the capacitive signal lines 19 (capacitive electrodes 20). The second insulation film 12 is formed by a CVD method, for example.

In this case, any one of the gate line layer 18, the gate electrode GT and the capacitive signal line 19 has the three-layered structure, wherein each layer has a substantially trapezoidal shape with a width thereof increased in ascending order of the intermediate layer 7., the uppermost layer 8 and the lowermost layer 6. Accordingly, it is possible to obtain an advantageous effect that a so-called coverage by the second insulation film 12 is enhanced. Further, the intermediate layer 7 of any one of the gate line layer 18, the gate electrode GT and the capacitive signal line 19 is formed such that the intermediate layer 7 is retracted from the uppermost layer 8 and the lowermost layer 6 and the second insulation layer 12 intrudes into these retracted portions whereby the coverage can be surely performed.

Then, after the formation of the second insulation film 12, a step in which so-called annealing is performed at a temperature of approximately 400° C. so as to activate the implanted dopant in the semiconductor layer 4 is executed. In this case, as the intermediate layer 7 of any one of the gate line layer 18, the gate electrode GT and the capacitive signal line 19, an Al—Si alloy film is used. Although there exists no problem with respect to the front and back surfaces of the intermediate layer 7, that is, portions which are brought into contact with the uppermost layer 8 and the lowermost layer 6 made of an Mo—W alloy film, it is impossible to avoid the generation of a so-called hillock on side wall surfaces of the intermediate layer 7. The hillock means a large number of needle-like conductive materials which grow from an Al material. The higher the temperature at the time of annealing, the growth of the hillock is accelerated and hence, there arises a problem that the hillock is electrically connected with other conductive layer (for example, the drain line layer 14 or a source electrode described later) which is arranged close to the hillock.

However, in this embodiment as described above, the intermediate layer 7 is configured such that the side wall surfaces thereof are properly retracted from the side wall surfaces of the uppermost layer 8 and the lowermost layer 6 and hence, even when the hillock grows on the side wall surfaces, the growth of the hillock can be suppressed by an amount corresponding to the retraction of the side wall surfaces. In other words, this embodiment has an advantageous effect that a drawback attributed to the hillock can be sufficiently reduced.

Then, on an upper surface of the second insulation layer 12, the drain line layers 14 which extend in the y direction in the drawing and are arranged in parallel in the x direction in the drawing are formed. These drain line layers 14 define the pixel regions together with the above-mentioned gate line layers 18.

The drain line layer 14 has a portion thereof connected to a drain region 10D (a side which is connected with the drain line layer 14 is referred to as the drain region in this specification) of the thin film transistor TFT via a contact hole CH2 which is formed in the second insulation film 12 and the first insulation film 5.

Further, source electrodes 22 are formed simultaneously with the formation of the drain line layers 14, wherein the source electrode 22 is formed over an upper surface of the source region 10S of the thin film transistor TFT and slightly extends toward the pixel region from the upper surface. The source electrode 22 is also connected to the source region 10S of the thin film transistor TFT via a contact hole CH3 which is formed in the second insulation film 12 and the first insulation film 5.

Then, a third insulation film 15A and a fourth insulation film 15B are sequentially formed over the upper surface of the second insulation film 12 such that the third insulation film 15A and the fourth insulation film 15B also cover the drain line layers 14 and the source electrodes 22. The third insulation film 15A is formed of SiO₂ or SiN, for example, and the fourth insulation film 15B is formed of an organic material film such as resin, for example.

These third insulation film 15A and fourth insulation film 15B function as protective films for obviating the direct contact of the thin film transistors TFT with the liquid crystal. By forming the fourth insulation film 15B using the organic material film and by relatively increasing a film thickness of the fourth insulation film 15B, it is possible to flatten a surface of the fourth insulation film 15B, whereby it is possible to obtain advantageous effects that the orientation of the liquid crystal can assume a favorable state and, at the same time, the dielectric constant of the protective film as a whole can be reduced.

On an upper surface of the fourth insulation film 15B, pixel electrodes 17 made of a light transmitting material such as an ITO (Indium-Tin-Oxide) film, for example, are formed and the pixel electrode 17 is formed over the whole area of the pixel region. Since the protective film is configured to have the small dielectric constant as described above, the protective film is formed to make a periphery thereof overlapped with the drain line layers 14 and the gate line layers 18 and hence, the so-called numerical aperture of the pixels can be enhanced.

Here, the material of the pixel electrode 17 is not limited to the above-mentioned ITO film and it is needless to say that the pixel electrode 17 may be formed of a light transmitting material such as ITZO (Indium-Tin-Zinc-Oxide), IZO (Indium-Zinc-Oxide), SnO₂ (Tin-Oxide), In₂O₃ (Indium-Oxide) or the like.

The pixel electrode 17 has a portion thereof which is arranged close to the thin film transistor TFT connected to the source electrode 22 via a contact hole CH4 formed in the fourth insulation film 15B and the third insulation film 15A.

Here, the pixel electrode 17 forms a capacitive element Cstg2 which uses the fourth insulation film 15B and the third insulation film 15A as dielectric films between the pixel electrode 17 and the capacitive electrode 20, wherein the capacitive element Cstg2 is configured to be arranged parallel to the above-mentioned capacitive element Cstg1.

With respect to the pixel having such a constitution, when the scanning signal is supplied to the gate line layer 18, the thin film transistor TFT is turned on and the video signal from the drain line layer 14 which is supplied at the timing of supply of the scanning signal is supplied to the pixel electrode 17 through the thin film transistor TFT.

Then, the video signal supplied to the pixel electrode 17 is stored in the pixel electrode 17 for a relatively long time due to the capacitive elements Cstg (Cstg1, Cstg2).

Although Al—Si is used as the material of the intermediate layer 7 in this embodiment, the similar drawback arises in a material such as pure Al, Al—Cu, Al—Cu—Si or the like. Accordingly, it is needless to say that these materials can be also used as the material of the intermediate layer 7.

Further, there may be a case that an ionic material flows out from the intermediate layer 7 of the gate electrode at the time of forming the insulation film 12, for example, and the ionic material reaches the surface of the insulation film 5 thus contaminating the insulation film 5 whereby the characteristics of the thin film transistor TFT is degraded.

Further, there may arise a case in which during a step for forming the insulation film 12, the above-mentioned ionic material flows out to the surface of the insulation film 12 from the intermediate layer 7 of the gate electrode and this out flow continues until the completion of the insulation film 12 and a leak current is generated between the drain electrode or the source electrode which is formed thereafter and the gate electrode through the above-mentioned ionic material.

Accordingly, in this embodiment, by adopting the constitution in which the intermediate layer 7 of the gate electrode is retracted from other layer such as the lowermost layer 6 or the uppermost layer 8, the above-mentioned contamination path can be eventually elongated whereby the occurrence of the above-mentioned drawback can be suppressed.

In view of the above, the material of the intermediate layer 7 of the gate electrode is not limited to the material which is liable to easily generate the hillock and it is needless to say that any material which is liable to generate contamination which generates the leak current as described above can be used as the material of the intermediate layer 7. That is, a material such as Al—Nd, Al—Y, Al—Hf—Y can be used as the material of the intermediate layer 7. It is needless to say that this selection of the material of the intermediate layer 7 is also applicable to the embodiments described hereinafter.

<<Manufacturing Method>>

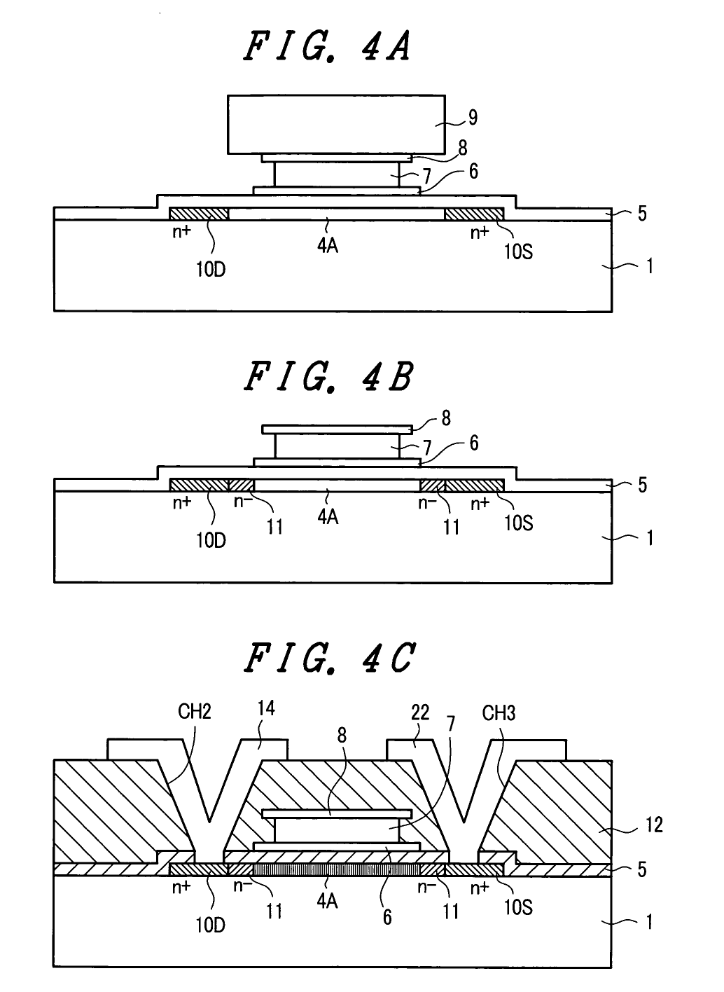

FIG. 4A to FIG. 4C are views showing essential steps of one embodiment of the manufacturing method of the pixel shown in FIG. 1 to FIG. 3. Here, the background films (the silicon nitride film 2 and the silicon oxide film 3) are omitted from the drawing.

First of all, in FIG. 4A, a photoresist film 9 is left in the region where a gate pattern is formed. Using the photoresist film 9 as a mask, an Mo—W alloy film constituting the uppermost layer 8, an Al—Si alloy film constituting the intermediate layer 7 below the uppermost layer 8 and an Mo—W alloy film constituting the lowermost layer 6 below the intermediate layer 7 which are exposed from the mask are sequentially etched.

In this case, a phosphoric acid system etchant is used as an etchant and the uppermost layer 8, the intermediate layer 7 and the lowermost layer 6 are respectively collectively etched using such an etchant. Then, by applying a so-called isotropic etching, side etching of approximately 0.3 μm to 1.0 μm is performed with respect to the photoresist film 9.

In this case, the film composition and the etchant which slightly accelerates the side etching of the intermediate layer 7 with respect to the lowermost layer 6 and the uppermost layer 8 are adopted. Alternately, after performing the collective etching, the intermediate layer 7 may be selectively subjected to side etching with respect to the lowermost layer 6 and the uppermost layer 8.

Due to such steps, the center axes in the extending direction of respective layers of the gate pattern are substantially aligned, while the widths (the widths in the direction which crosses the extending direction) of respective layers are set such that the widths are increased in ascending order of the intermediate layer 7, the uppermost layer 8 and the lowermost layer 6.

Further, to make the respective layers of the gate pattern have the similar cross-sectional structure, a material such as Ti or TiN is used as the material of the uppermost layer 8 and the lowermost layer 6 and the three layers may be collectively etched by dry etching. This is because that when a chloride system gas is used in dry etching, a dry etching rate of Al becomes faster than a dry etching rate of Ti.

Then, after forming the gate pattern in this manner, using the above-mentioned photoresist film 9 as a mask, phosphorous (P) is implanted to form n⁺ impurities regions in the semiconductor layer 4A thus forming the drain region 10D and the source region 10S.

Then, as shown in FIG. 4B, the photoresist film 9 is removed and n⁻ impurities are doped using the gate pattern as a mask whereby the LDD (Lightly Doped Drain) structures (LDD layers 11) are formed in the self-alignment manner between the drain region 10D and the source region 10S of the semiconductor layer 4A and the gate pattern.

Further, as shown in FIG. 4C, the second insulation film 12 is formed over the upper surface of the first insulation film 5 such that the second insulation film 12 also covers the gate patterns, the contact holes CH2 and CH3 are formed in the second insulation film 12, and the drain line layers 14 (drain electrodes) and the source electrodes 22 are formed on the second insulation film 12.

The second insulation film 12 is formed such that an SiO₂ film, for example, is formed by a CVD method, for example. After forming the second insulation film 12, annealing is performed at a temperature of approximately 400 degree centigrade for activating the dopant implanted into the semiconductor layer 4A.

Here, due to the heat generated at the time of forming the second insulation film 12 and at the time of annealing, the hillock grows from the intermediate layer 7 of the gate pattern. In this case, since the intermediate layer 7 is configured to be sandwiched between the lowermost layer 6 and the uppermost layer 8, the growth of the hillock is suppressed on a contact surface between the intermediate layer 7 and the lowermost layer 6 as well as on a contact surface between the intermediate layer 7 and the uppermost layer 8 by the lowermost layer 6 and the uppermost layer 8. However, the mutual dispersion is observed between the intermediate layer 7 and the lowermost layer 6 or between the intermediate layer 7 and the uppermost layer 8 at the time of heating and there may be a case in which the infiltration of the hillock or Al is generated beyond the lowermost layer 6 or the uppermost layer 8 due to such diffusion. Accordingly, it is appropriate to set film thicknesses of the lowermost layer 6 and the uppermost layer 8 to approximately 20 nm (when annealing is performed at a temperature of approximately 400 degree centigrade) or more.

Further, although the side wall surfaces of the intermediate layer 7 are not covered with other metal layer, the side wall surfaces of the intermediate layer 7 are configured to be retracted with respect to the side wall surfaces of the lowermost layer 6 and the uppermost layer 8. Accordingly, even when a slight amount of hillock is generated in the lateral direction, it is possible to avoid the generation of the hillock which extends upwardly and downwardly beyond the lowermost layer 6 and the uppermost layer 8.

The contact holes CH2 and CH3 which are formed in the second insulation film 12 and the first insulation film 5 are formed by continuous etching using a buffered hydrofluoric acid.

The drain line layer 14 (drain electrode) and the source electrode 22 have, for example, the three-layered structure formed of Ti/Al—Si/Ti, for example, and are formed such that after forming a resist pattern, the collective etching is performed by dry etching which uses a chlorine gas. In this case, it is needless to say that, as the material of the drain line layer 14 (drain electrode) and the source electrode 22, the three-layered structure formed of MoW/Al—Si/MoW is adopted in the same manner as the gate line layer 18, wherein the three-layered structure is processed by wet etching.

Although not shown in FIG. 4A to FIG. 4C, in steps which follow the step shown in FIG. 4C, the third insulation film 15A is formed using SiN, for example, by a CVD method. Thereafter, the third insulation film 15A is subjected to hydrogen annealing in a hydrogen atmosphere at a temperature of 400 degree centigrade. Also in this case, due to the constitution of the present invention, there arises no drawback attributed to the hillock of the intermediate layer 7 in the gate pattern during annealing.

Then, the fourth insulation film 15B is formed by applying a photosensitive acrylic resin and, thereafter, by performing the exposure and development of the photosensitive acrylic resin. Then, the contact hole CH4 is formed in the fourth insulation film 15B. Thereafter, scum of the photosensitive acrylic resin is removed by oxygen ashing.

Thereafter, the ITO film is formed and the pixel electrode 17 is formed by performing the selective etching using a photolithography technique. As etching applicable to this case, wet etching which uses oxalic acid, aqua regia or hydrobromic acid, for example, is adopted.

Embodiment 2.

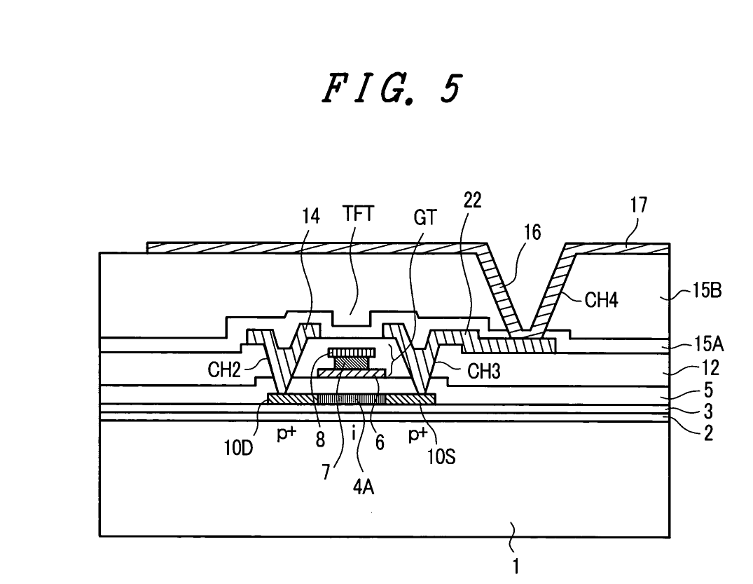

FIG. 5 is a cross-sectional view showing another embodiment of the display device according to the present invention and corresponds to FIG. 2.

The constitution which makes this embodiment different from the constitution shown in FIG. 2 lies in that while the thin film transistor TFT shown in FIG. 2 is an n-channel type MIS transistor (Metal Insulator Semiconductor), FIG. 5 shows a p-channel type MIS transistor.

With respect to the p-channel type MIS transistor, in a scanning signal drive circuit which supplies scanning signals to gate line layers 18 or a video signal drive circuit which supplies video signals to the drain line layers 14, a complementary type transistor is formed together with the n-channel type MIS transistor thus constituting a CMOS (or CMIS) type transistor.

Unlike the n-channel type MIS transistor, the degradation of characteristics attributed to an electric field at the drain end portions in the p-channel type MIS transistor has the relatively small significance and hence, the necessity to adopt the LDD structures shown in FIG. 2 is small and it is sufficient to form p⁺ regions which constitute the source region 10S and the drain region 10D at both ends of the channel layer right below the gate electrode GT as shown in FIG. 5.

Also in this case, the gate electrode GT and the gate line layer 18 have the three-layered structure, for example, wherein the center axes in the extending direction of respective layers are substantially aligned with each other and their widths (widths in the direction which crosses the extending direction) are formed such that the widths are increased in ascending order of the intermediate layer 7, the uppermost layer 8 and the lowermost layer 6.

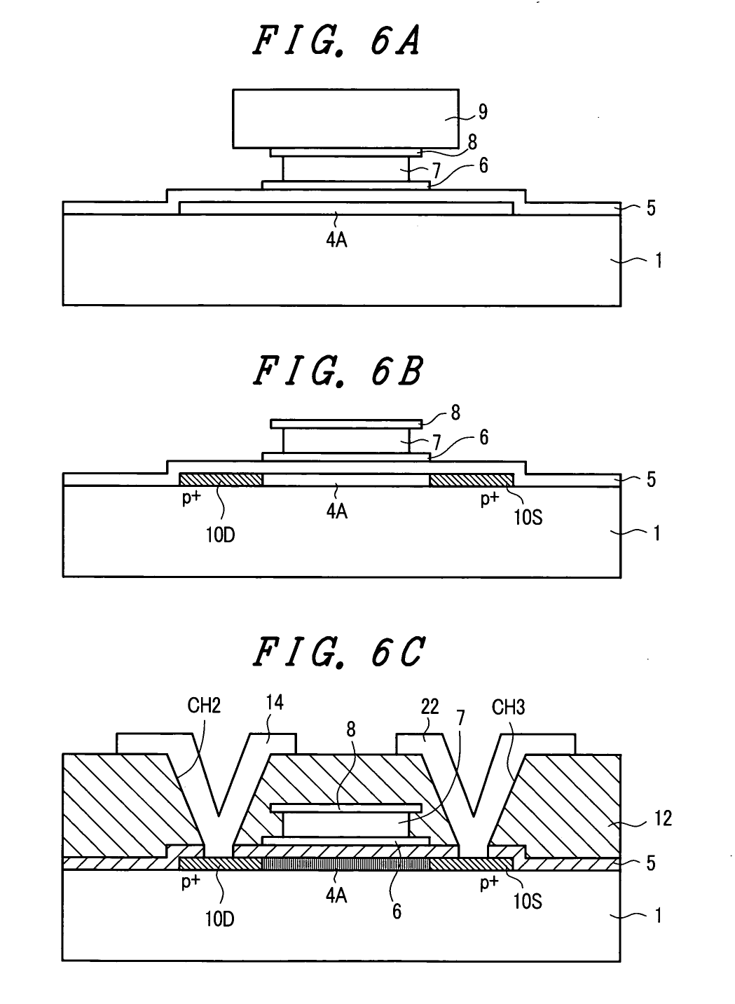

FIG. 6A to FIG. 6C are views showing steps of one embodiment of the manufacturing method of the above-mentioned display device and correspond to FIG. 4A to FIG. 4C.

This embodiment differs from the embodiment shown in FIG. 4A to FIG. 4C with respect to points that the photoresist film 9 which is provided for forming the gate pattern is removed after the formation of the gate pattern and p⁺ impurities made of boron (B), for example, are implanted using the gate pattern as a mask.

Here, when the p-channel type MIS transistor is formed in parallel to the n-channel type MIS transistor to form the CMOS constitution, the source region 10S, the drain region 10D and the LDD structure of the n-channel type MIS transistor are formed and, thereafter, at least the n-channel type MIS transistor is covered with the mask, a photoresist film having an opening is formed over a portion where the p-channel type MIS transistor is formed, and p⁺ impurities are counter-doped.

Further, after the formation of the second insulation film 12, annealing is collectively performed for activating the p-channel type MIS transistor and the n-channel type MIS transistor.

Embodiment 3.

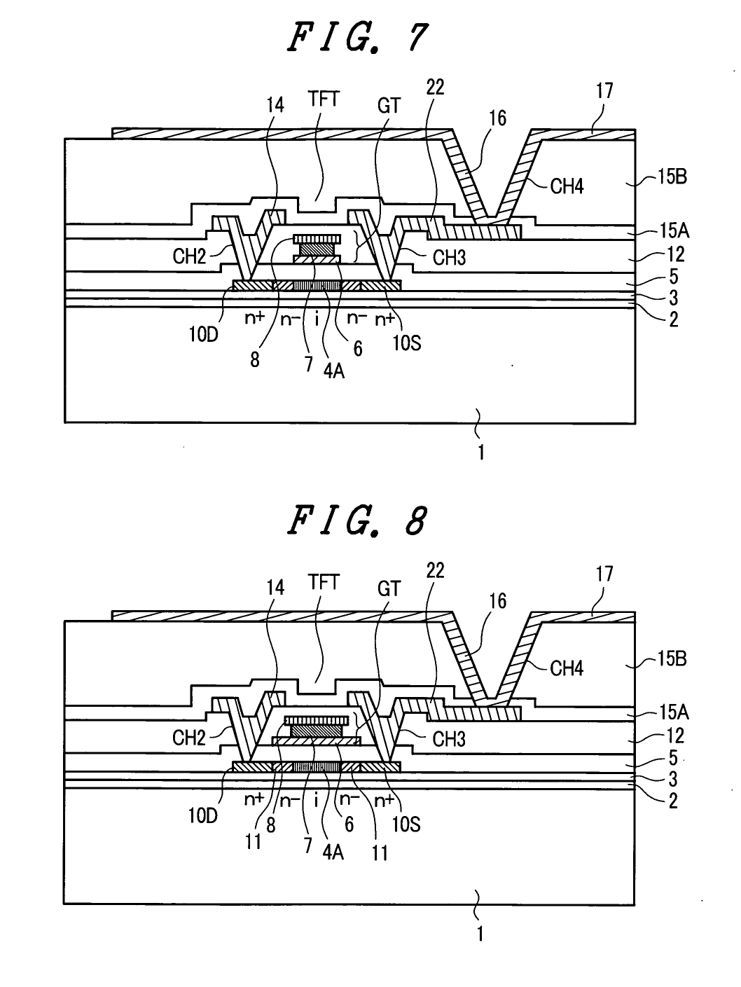

FIG. 7 is a view for explaining another embodiment of the display device according to the present invention and corresponds to FIG. 2.

The constitution which makes this embodiment different from the embodiment shown in FIG. 2 lies in the structure of the gate electrode GT of the thin film transistor TFT.

The gate electrode GT has the three-layered structure formed of respective layers made of Ti, Al—Si, Ti respectively which correspond to layers starting from the lowermost layer 6 to the uppermost layer 8. In this case, Ti which is the material of the lowermost layer 6 and the uppermost layer 8 is metal having a high melting point similar to Mo—W shown in FIG. 2 and the hillock which grows at contact surfaces between the Al—Si of the intermediate layer 7 and Ti can be avoided due to the presence of Ti.

Further, while the side wall surfaces of the intermediate layer 7 made of Al—Si are retracted from the side wall surfaces of the uppermost layer 8 and the lowermost layer 6, the uppermost layer 8 and the lowermost layer 6 have the substantially same width (width in the direction orthogonal to the extending direction).

With the use of Ti as the materials of the lowermost layer 6 and the uppermost layer 8 of the gate electrode GT, a cross-sectional shape shown in the drawing is formed by reactive ion etching (RIE) which enables the anisotropic etching. This is because a dry etching rate of Ti is faster than a dry etching rate of Al.

Embodiment 4.

FIG. 8 is a view for explaining another embodiment of the display device according to the present invention and corresponds to FIG. 2.

The constitution which makes this embodiment different from the embodiment shown in FIG. 2 lies in that the so-called GOLD (Gate Overlapped LDD) structure is adopted.

That is, with respect to the semiconductor layer 4A, structurally, a channel layer is formed at the center region thereof, LDD layers 11 are formed outside the channel layer, and source regions 10S and the drain region 10D are formed outside the LDD layers 11. In such a structure, the LDD layers 11 are formed such that the LDD layers 11 are overlapped with the gate electrode GT.

Further, in this embodiment, the channel layer is formed such that the channel layer is overlapped with a material layer which constitutes the uppermost layer 8 of the gate electrode GT, while the LDD layers 11 are formed such that the LDD layers 11 are overlapped with a material layer which constitutes the lowermost layer 6 formed in a projected manner from the material layer which constitutes the uppermost layer 8 of the gate electrode GT. Accordingly, both of the source region 10S and the drain region 10D are formed in the direction extending outwardly from end portions of the material layer which constitutes the lowermost layer 6 of the gate electrode GT.

In the thin film transistor TFT having such a constitution, by extending the gate electrode GT above the LDD layers 11 of the semiconductor layer 4A, an amount of the series resistance corresponding to the LDD regions can be reduced and hence, an ON current can be increased.

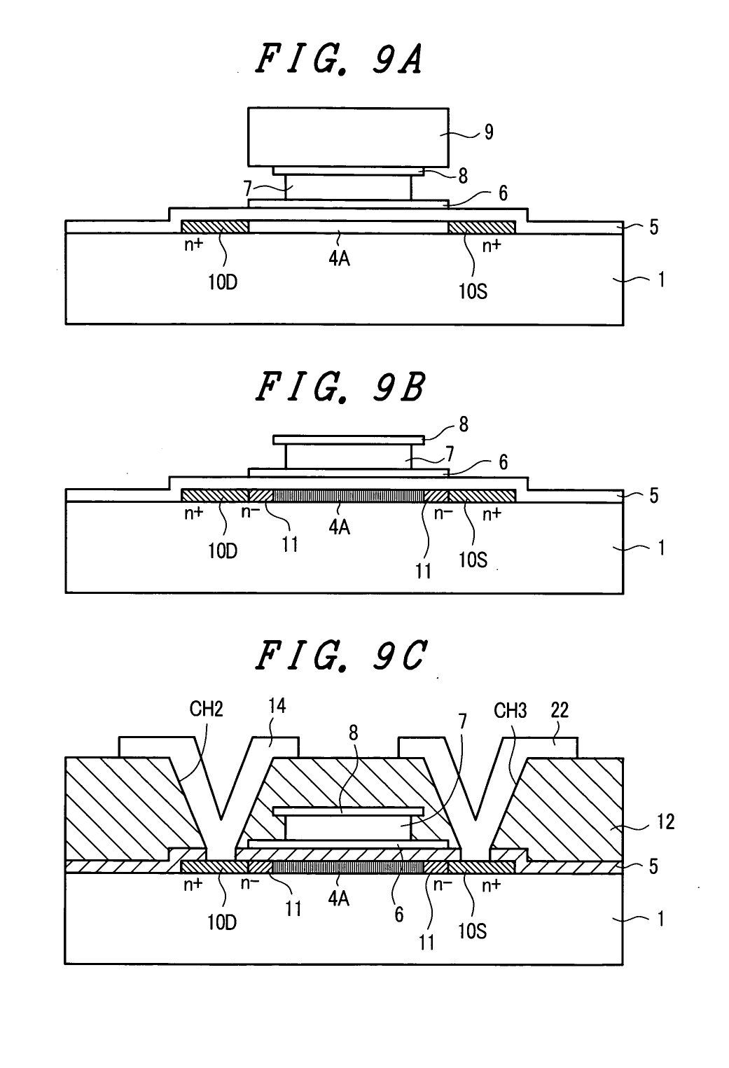

FIG. 9A to FIG. 9C are views showing one embodiment of the manufacturing method of the above-mentioned display device and correspond to FIG. 4A to FIG. 4C.

The constitution which makes this embodiment different from the embodiment shown in FIG. 4A to FIG. 4C lies in that a film thickness of the lowermost layer 6 of the gate pattern which is constituted by a sequential laminated body of Mo—W, Al—Si, Mo—W is made relatively small and is set to approximately 20 nm, for example.

Then, using the photoresist film 9 at the time of forming the gate pattern as a mask, n⁺ impurities are implanted and, thereafter, the photoresist film 9 is removed. Thereafter, n⁻ impurities are implanted using the gate pattern as a mask.

In this case, the n⁻ impurities are doped into the inside of the semiconductor layer 4A after passing through the lowermost layer 6 of the gate pattern and the LDD layers 11 are formed.

Embodiment 5.

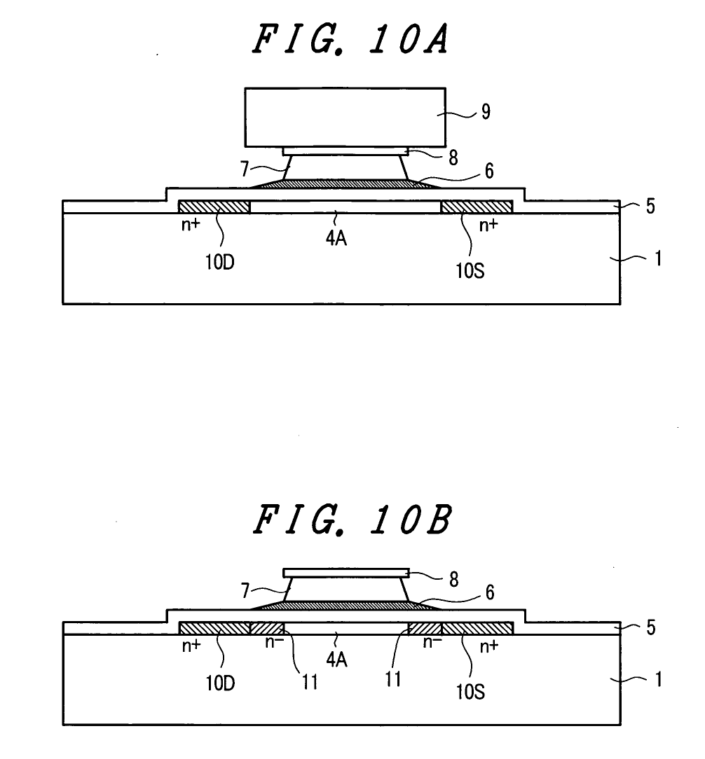

FIG. 10A and FIG. 10B are views showing another embodiment of the manufacturing method of the display device according to the present invention and correspond to FIG. 9A and FIG. 9B.

The constitution which makes this embodiment different from the embodiment shown in FIG. 9A and FIG. 9B lies in that the gate electrode GT having the three-layered structure uses Mo—Cr as the material of the lowermost layer 6 thereof, Al—Si as the material of the intermediate layer 7 thereof, and Mo—W as the material of the uppermost layer 8 thereof, for example.

Then, an alloy ratio of the Mo—Cr of the lowermost layer 6 is set such that an etching rate thereof becomes approximately one tenth of an etching rate of the Mo—W of the uppermost layer 8. For example, the lowermost layer 6 is made of Mo-2.5 wt % Cr and has a film thickness of 20 nm at the time of forming the film, for example, and the uppermost layer 8 is made of Mo-20 wt % W and has a film thickness of 50 nm, for example.

In performing the wet etching using the photoresist film 9, for example, the etching is performed such that the side etching widths of the intermediate layer 7 and the uppermost layer 8 become approximately 1 μm during etching of the lowermost layer 6 of the gate pattern.

Side etching amounts of the intermediate layer 7 and the uppermost layer 8 directly correspond to the width of the LDD layers.

This implies that by changing the etching rate at the time of forming the gate pattern by ten times or around ten times, it is possible to control not only the width of the LDD layers but also an overlapped width of the LDD layer with the gate electrode GT. Accordingly, it is possible to obtain an advantageous effect that both of an ON current and an OFF current of the thin film transistor TFT can be changed based on this control.

Here, as mentioned above, by adopting the wet etching in the formation of the gate pattern, the damage can be eliminated and the favorable transistor characteristics can be obtained.

Embodiment 6.

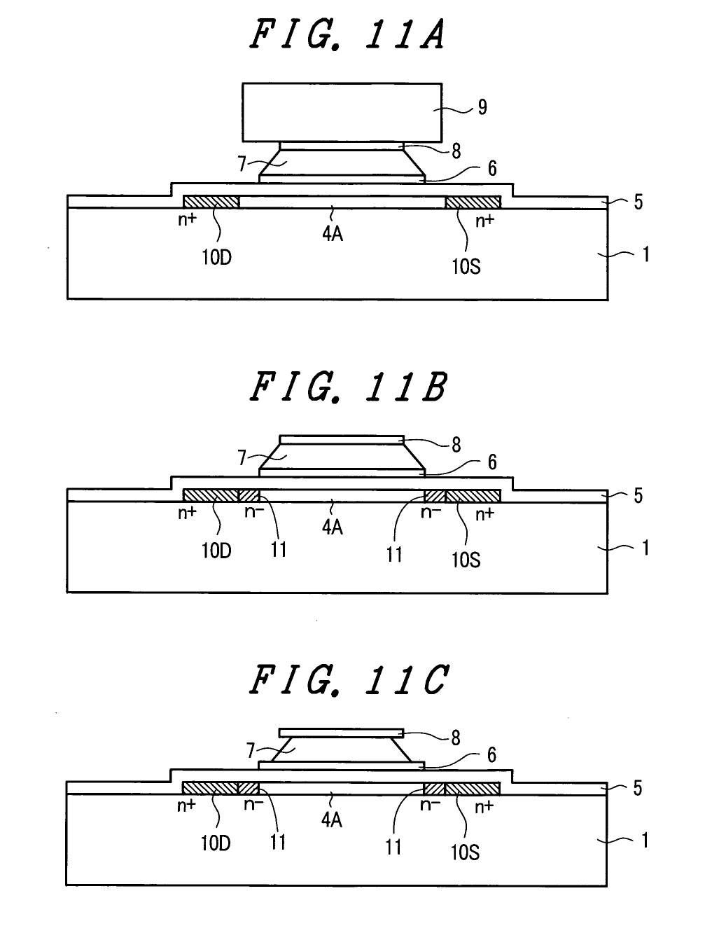

FIG. 11A to FIG. 11C are views showing another embodiment of the display device according to the present invention and correspond to FIG. 4A and FIG. 4B.

The constitution which makes this embodiment different from the embodiment shown in FIG. 4A and FIG. 4B lies in that the gate pattern having the three-layered structure uses Mo—W as the material of the lowermost layer 6 thereof, Al—Si as the material of the intermediate layer 7 thereof, and Mo—W as the material of the uppermost layer 8 thereof and, at the same time, for example, these respective layers are subjected to the collective wet etching using a phosphorous-system etchant, for example, and, thereafter, the light etching is performed using a dilute hydrofluoric acid.

In the gate pattern formed in this manner, the width of the uppermost layer 8 is set smaller than the width of the lowermost layer 6, and the width of the intermediate layer 7 is set such that the width changes substantially linearly in the direction from the uppermost layer 8 to the lowermost layer 6 within a range from a width smaller than the width of the uppermost layer 8 to a width smaller than a width of the lowermost layer 6. In other words, the intermediate layer 7 has side wall surfaces thereof formed in a so-called normal tapered shape such that the surface which is brought into contact with the uppermost layer 8 is retracted from the uppermost layer 8 and the surface which is brought into contact with the lowermost layer 6 is retracted from the lowermost layer 6.

That is, as shown in FIG. 11A, when the wet etching is collectively performed with respect to the gate pattern using the photoresist film 9 and, at the same time, using the phosphorus-system etchant, for example, by adopting the same material having the same etching rate with respect to the lowermost layer 6 and the uppermost layer 8, the etching of the uppermost layer 8 is performed first and hence, the cross section of the gate pattern consisting of the uppermost layer 8, the intermediate layer 7 and the lowermost layer 6 is formed in the normal tapered shape.

Then, with the use of the photoresist film 9, the drain region 10D and the source region 10S are formed by implanting the n⁺ impurities.

Further, as shown in FIG. 11B, the LDD layer 11 is formed by implanting n⁻ impurities after removing the photoresist film 9.

Thereafter, as shown in FIG. 1C, the so-called light etching of the gate pattern is performed by cleaning the gate pattern using a dilute hydrofluoric acid of 1:99. Accordingly, the intermediate layer 7 is selectively etched with respect to the uppermost layer 8 and the lowermost layer 6 so as to retract the side wall surfaces of the intermediate layer 7.

In this case, based on time required for the cleaning, a retracting amount of the sidewall surfaces of the intermediate layer 7 can be controlled. When hydrofluoric aqueous solution of 0.5%, for example, is used, it is possible to obtain the retracting amount of the approximately 0.2 μm.

Further, due to such a cleaning operation, it is also possible to obtain an advantageous effect that the impurities adhered to the surface of the substrate by implantation performed in the preceding step can be removed. Additionally, it is possible to obtain an advantageous effect that the cleaning operation after the formation of various types of insulation films can be omitted.

The above-mentioned respective embodiments may be used in a single form or in combination. This is because the advantageous effects of respective embodiments can be obtained in a single form or synergistically.

Further, although the example in which pure Al or the Al alloy is used as the material of the intermediate layer 7 of the gate pattern is explained in the above-mentioned respective embodiments, pure Ag, an Ag alloy, pure Cu or a Cu alloy may be used in place of pure Al or the Al alloy. The uppermost layer 8 and the lowermost layer 6 may be made of metal having a melting point higher than a melting point of the material of the intermediate layer 7. The intermediate layer 7 may be formed of two layers or more.

Further, the above-mentioned respective embodiments adopt the structure in which the intermediate layer 7 is retracted from the lowermost layer 6 and the uppermost layer 8 in all side surfaces of the gate pattern. However, it is sufficient that such a structure is applied to either one of the portion (gate electrode GT) of the thin film transistor or the portion which crosses the drain line (portion of the gate pattern where the gate line layer 18 crosses the drain line layer 14) in the gate pattern. This is because the drawback caused by the hillock from the intermediate layer 7 or the contamination becomes apparent in such portions.

Further, in the above-mentioned respective embodiments, the explanation is made with respect to the liquid crystal display device. However, it is needless to say that the present invention is applicable to any display device which includes thin film transistors such as an organic EL (Electro Luminescence) display device or the like, for example. This is because the organic EL display device also includes a pixel electrode and a counter electrode which sandwich an organic light emitting layer therebetween on each pixel formed on a surface of a substrate, and also includes thin film transistors which are driven in response to scanning signals from gate line layers and supply video signals from drain signal lines to the pixel electrodes.

As can be clearly understood from the foregoing explanation, according to the display device of the present invention, it is possible to provide the display device provided with the gate signal lines and the gate electrodes of the thin film transistors which can prevent the generation of hillock and can reduce the resistance in spite of the simple structure.

What is claimed is:

1. A display device having thin film transistors on a substrate thereof, wherein
the display device includes gate patterns in each of which a gate line and a gate electrode of the thin film transistor are integrally formed,
the gate pattern is constituted by at least three-layered films consisting of a lowermost layer, an intermediate layer formed of at least one layer and an uppermost layer at least at either a portion of the thin film transistor or a portion of the gate pattern which crosses a drain line,
the intermediate layer is formed of a material selected from the group consisting of pure Al, an Al alloy, pure Ag, an Ag alloy, pure Cu and a Cu alloy, and the uppermost layer and the lowermost layer are formed of a metal having a melting point higher than a melting point of the material of the intermediate layer, and
end portions of the intermediate layer are retracted from end portions of the uppermost layer and end portions of the lowermost layer.

2. A display device according to claim 1, wherein the uppermost layer and the lowermost layer are formed of pure Mo or an Mo alloy.

3. A display device according to claim 1, wherein the uppermost layer and the lowermost layer are formed of an Mo—W alloy.

4. A display device according to claim 1, wherein end portions of the uppermost layer are retracted from end portions of the lowermost layer.

5. A display device according to claim 1, wherein the thin film transistor includes a semiconductor layer and the gate electrode is arranged above the semiconductor layer.

6. A display device according to claim 1, wherein the thin film transistor includes a polycrystalline semiconductor layer.

7. A display device having thin film transistors on a substrate thereof, wherein
the display device includes gate patterns in each of which a gate line and a gate electrode of the thin film transistor are integrally formed, and an insulation film which covers the gate patterns,
the gate pattern is constituted by at least three-layered films consisting of a lowermost layer, an intermediate layer formed of at least one layer and an uppermost layer at least at either one of a portion of the thin film transistor or a portion of the gate pattern which crosses a drain line,
the intermediate layer is formed of a material selected from the group consisting of pure Al, an Al alloy, pure Ag, an Ag alloy, pure Cu and a Cu alloy, and the uppermost layer and the lowermost layer are formed of a metal having a melting point higher than a melting point of the material of the intermediate layer, and
end portions of the uppermost layer of the gate electrode are retracted from end portions of the lowermost layer and, at the same time, end portions of the intermediate layer of the gate electrode are retracted from end portions of the uppermost layer and end portions of the lowermost layer.

8. A display device according to claim 7, wherein the thin film transistor includes a semiconductor layer and the gate electrode is arranged above the semiconductor layer.

9. A display device according to claim 8, wherein the uppermost layer and the lowermost layer are formed of pure Mo or an Mo alloy.

10. A display device according to claim 8, wherein the uppermost layer and the lowermost layer are formed of an Mo—W alloy.

11. A display device according to claim 8, wherein the uppermost layer and the lowermost layer are formed of an Mo alloy, and an etching rate of the Mo alloy of the uppermost layer is faster than an etching rate of Mo alloy of the lowermost layer.

12. A display device according to claim 11, wherein the lowermost layer is formed of an Mo—Cr alloy and the uppermost layer is formed of an Mo—W alloy.

13. A display device according to claim 7, wherein the semiconductor layer includes an LDD region, and the lowermost layer of the gate electrode has at least a portion thereof overlapped with the LDD region.

14. A display device according to claim 7, wherein the thin film transistor includes a polycrystalline semiconductor layer.
